(19) United States
(12) Patent Application Publication
(10) Pub. No.: US 2010/0163094 A1
(43) Pub. Date: Jul. 1, 2010

(54) Method and System for Harvesting Artificial Light

(76) Inventor: Hughie Kelly, (US)

Correspondence Address: Hughie Kelly, 3735 Camden St. SE, Washington, DC, 20020, US

(21) Appl. No.: 12/344,534

(22) Filed: Dec. 28, 2008

(51) Int. Cl. H01L 31/042; H02N 6/00

(52) U.S. Cl. 136/244; 136/252

(57) ABSTRACT

Method and system is provided for harvesting artificial light. Photovoltaic systems are placed in locations where artificial light is available such as along highways, airports, stadiums and subways. Photovoltaic systems harvest light energy provided by artificial sources, such as automobile headlights and overhead lighting. Photovoltaic systems convert energy provided by artificial sources into electricity. Electricity is sent to transfer stations, battery storage or otherwise stored or used such that demand on the power grid is reduced.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO SEQUENCE LISTING, A TABLE, OR A COMPUTER PROGRAM LISTING COMPACT DISC APPENDIX

Not applicable.

### BACKGROUND OF THE INVENTION

Our society is faced with the ever increasing demand for energy. We are overly dependent on fossil fuels, which cause serious harm to the environment aside from being a finite resource. Air pollution, water pollution and global warming have all reached unacceptable levels and our society has finally recognized the need for both alternative sources and conservation. Even as the demand for energy has increased little effort has been made to recycle energy. While we recycle a multitude of materials, such as shopping bags, cans, plastic, and paper, little progress has been made with respect to recycling energy. The invention described herein provides a method and system for harvesting energy emitted by artificial light sources so that it may be reused.

### FIELD OF THE INVENTION

The current invention relates generally to the conversion of artificial light into electricity.

### REFERENCES CITED

| | | |
|---|---|---|
| 4,017,725 | Apr. 12, 1977 | Roen |
| 4,369,498 | Jan. 18, 1983 | Schulte |

### BRIEF SUMMARY OF THE INVENTION

Every day in cities and towns across the United States and the world precious energy that could be captured is lost forever. The invention described herein provides a method and system for harnessing and reusing this energy and thereby addresses the need to conserve and recycle energy.

It is widely known that it is inefficient to use artificial lighting as a source of power because it requires more electricity to power the artificial light than can be generated by harvesting that light. As such, artificial lighting has not been viewed as a useful tool in the generation of electricity. The flaw in the historical view of artificial light, however, is the failure to recognize that artificial lighting is used for a multitude of reasons regardless of whether it will be used to subsequently generate electricity. Common experience shows that we use lighting in an abundance of situations, and often when natural sunlight is not available, for the obvious reason—so that we can see. For example, we use artificial lighting to illuminate the inside of homes and businesses, public places such as stadiums, subways, shopping malls, and airports. And, of course, our cars have headlights in order to illuminate the road in front of us so that we may see where we are driving at night. We do not use artificial light in any of these situations to generate electricity but out of the basic need to see what we are doing and where we are going. Thus, the light is there being used, while any resulting energy simply dissipates. The present invention proposes that this light, which we already use for other purposes, may also be used to generate electricity and thereby reduce our overall energy demand. In essence, the invention proposes that we recycle artificial light—a resource that would otherwise be wasted.

The invention is the use of photovoltaic panels or systems to harvest artificial light. The photovoltaic panels or systems are placed in locations where artificial light is available. There are a multitude of locations where photovoltaic panels or systems may be paced to capture artificial light. For example, photovoltaic panels or systems may be placed along highways or roadways where vehicle headlights cast light, such as described in more detail in the Detailed Description of the Invention. Photovoltaic panels or systems may also be placed in stadiums, which use large, intense lighting systems for long periods of time—often for many hours or days after an event is completed. The photovoltaic panels or systems could be placed in a variety of locations, including light supports, billboards, stadium walls and supports, or even on stadium seating for collection after fans have left. Photovoltaic panels or systems may also be placed in and around airports, such as along concourses, ticketing areas, and passenger pick-up and drop-off areas where lighting is used around the clock. Similarly, subway stations or other indoor or underground facilities are well lit 24 hours a day for security reasons. The photovoltaic panels or systems could be hung from or even embedded in walls, pillars, and flooring. The same concept can be applied in private residences or businesses. Photovoltaic panels could be affixed to or embedded in the walls, floors, or other structural supports of residences or businesses. Additionally, the photovoltaic panels could be placed on free-standing or independent fixtures that may be placed in areas where artificial lighting is concentrated. There are any number of locations or situations where the invention could be placed, either fixedly or temporarily in order to collect artificial light.

According to the invention, the photovoltaic panels or systems then harvest the light energy provided by the artificial sources and convert that energy into electricity. That electricity may then be used at the site of the photovoltaic panels to, for example, power street sign, subway station, or home lighting, among other types of on-site lighting or for other on-site electricity needs. Or the electricity may be sent via conventional connections to transfer stations or battery storage. In whatever manner the electricity is used or stored by the invention, it has the effect of reducing demand, either by providing a source of electricity at the site or by providing additional electricity for other users who would traditionally derive all of their electricity needs from the power grid. As energy has become more valuable and as the pressure for conservation and energy independence have become more critical, the role of the current invention is made clear.

These and further and other objects and features of the invention are apparent in the disclosure, which includes the above and ongoing written specification, with the claims and the drawings.

### BRIEF DESCRIPTION OF THE SEVERAL VIEWS OF THE DRAWINGS

FIG. 1 shows a section of I-95 as it splits to I-395 and I-95/I-495. There is an elevated roadway that crosses above. To the left there is a riser that supports another exit. FIG. 1 shows jersey walls, elevated roadway supports and exterior side walls, a riser and light supports where the invention could be used.

FIG. 2 shows a section of I-395. There is an elevated roadway to the left. FIG. 2 shows jersey walls, elevated roadway supports and exterior side walls, a riser, light supports, and the underside of the elevated roadway where the invention could be used.

FIG. 3 shows a section of I-395 with overhead signs directing traffic to VA-644 and to I-95. FIG. 3 shows jersey walls, traffic signs, and sign supports where the invention could be used.

### DETAILED DESCRIPTION OF THE INVENTION

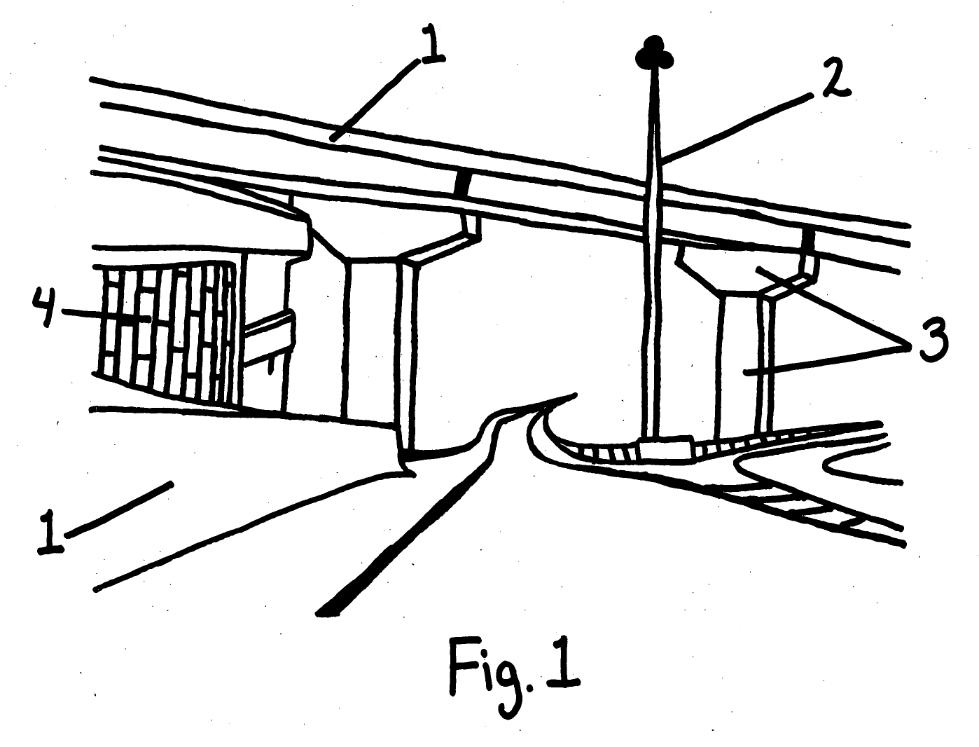

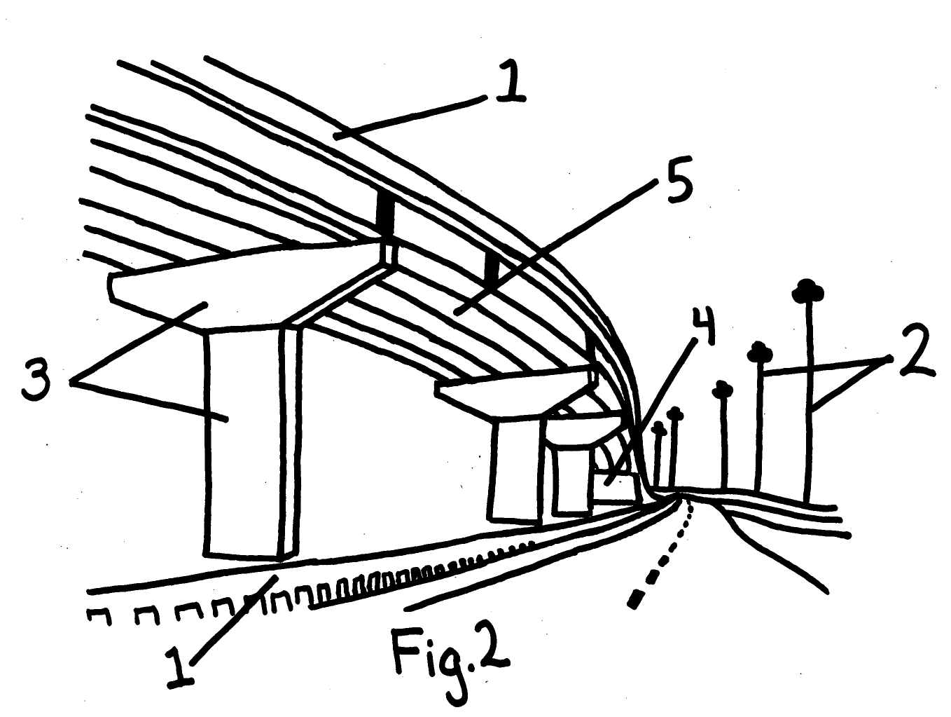

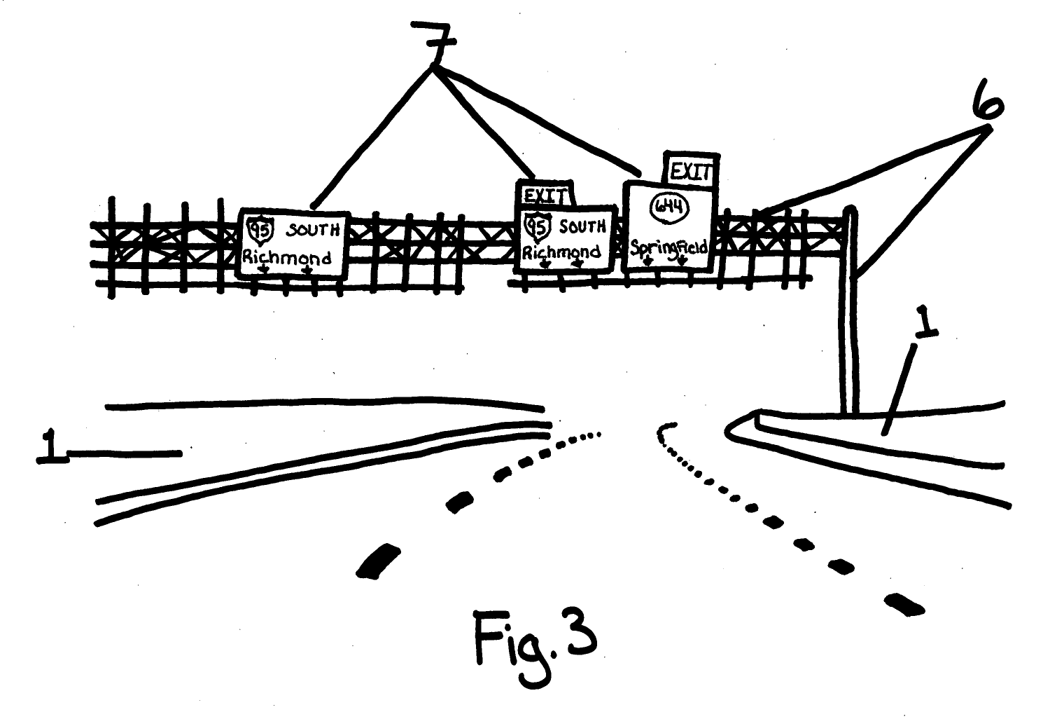

Each morning and evening, local television newscasters provide rush-hour updates. Everyone can easily see the incredible glare given off by a huge snake of motor vehicle headlights. In one embodiment of the invention the light given off by motor vehicle headlights is harvested by photovoltaic panels or systems and changed into electricity that may then be used, transferred or stored. Photovoltaic panels or systems are placed along highways in areas where motor vehicle headlights cast light. This embodiment can be used on any street, road, avenue, boulevard, highway, toll plaza or anywhere motor vehicles travel and shine their headlights. As shown in FIGS. 1, 2, and 3, panels may be placed in or on jersey walls 1, light supports 2, elevated roadway supports or other supports 3, risers 4, on or under elevated roadways 5, sign supports or the backs of sign supports 6, and on roadside or overhead highway and street signs or the backs of signs 7. In addition, panels may be placed on noise barriers, embankment supports and buildings that are near to or abut roadways or free-standing structures may be used to mount photovoltaic panels or systems. Any number of methods may be used to position panels in locations where light is cast. For example, the panels may be embedded in, removably affixed to, or hung from the various locations where light is cast. Or panels may be mounted on or to a free-standing structure that can be moved or positioned as needed. The panels collect light emitted from motor vehicle headlights and convert this artificial light energy into electricity. This electricity, which is collected from automobile headlights as opposed to solar lighting systems, may be used at the point of conversion to, for example, power street lights or lights used to illuminate street signs or it may be sent to transfer stations or battery storage. This energy can be used in countless ways so as to reduce demand on local power grids, such as by lighting roadways or for private consumption by individuals. Although the motor vehicle itself is a source of pollution, the light energy provided by the headlights is a clean, non-polluting source of energy. This non-polluting, renewable energy source is a reliable, long-term, cost-effective and efficient method of providing electric power.

Other possible applications of the invention include, for example: stadiums, where huge lighting systems are used long after events have concluded; airports, which use tremendous amounts of energy lighting passenger pick-up and drop-off areas, concourses and ticket areas; and subway stations.

It is to be understood that the present invention is not limited to the embodiments described here. Modifications and variations of the invention may be employed or constructed without departing from the scope of the invention which is defined by the scope of the claims.

The invention claimed is:

1. A method of harvesting artificial light, comprising the steps of: placing one or more photovoltaic cells in locations where artificial light is concentrated; connecting photovoltaic cells to user, transfer stations or storage facilities; harvesting artificial light emitted from artificial sources; converting artificial light into electricity; using electricity or sending electricity to transfer stations or storage facilities such that demand on the power grid is reduced.

2. The method of claim 1, wherein the photovoltaic cells are placed along highways so as to harvest artificial light emitted from automobile headlights.

3. The method of claim 1, wherein the photovoltaic cells are placed in stadiums so as to harvest artificial light emitted from stadium lighting.

4. The method of claim 1, wherein the photovoltaic cells are placed in and around airports so as to harvest artificial light emitted in passenger pick-up and drop-off areas, ticketing areas, and concourses.

5. The method of claim 1, wherein the photovoltaic cells are placed in subway stations so as to harvest artificial light emitted from station lighting.

6. The method of claim 1, wherein the photovoltaic cells are placed on the interior walls of homes or businesses so as to harvest artificial light emitted from indoor lighting.

7. A system of recycling artificial light, comprising: one or more photovoltaic cells placed in locations where artificial light is concentrated; wherein said photovoltaic cells are connected to transfer stations or storage facilities; and wherein said photovoltaic cells harvest artificial light emitted from artificial sources and convert said artificial light into electricity; wherein said electricity is used or sent to transfer stations or storage facilities such that demand on the power grid is reduced.

8. The system of claim 7, wherein the photovoltaic cells are placed along highways so as to harvest artificial light emitted from automobile headlights.

9. The system of claim 7, wherein the photovoltaic cells are placed in stadiums so as to harvest artificial light emitted from stadium lighting.

10. The system of claim 7, wherein the photovoltaic cells are placed in and around airports so as to harvest artificial light emitted in passenger pick-up and drop-off areas, ticketing areas, and concourses.

11. The system of claim 7, wherein the photovoltaic cells are placed in subway stations so as to harvest artificial light emitted from station lighting.

12. The system of claim 7, wherein the photovoltaic cells are placed on the interior walls of homes or businesses so as to harvest artificial light emitted from indoor lighting.
